(19) United States
(12) Patent Application Publication
(10) Pub. No.: US 2004/0212026 A1
(43) Pub. Date: Oct. 28, 2004

(54) MEMS device having time-varying control

(75) Inventors: Andrew L. Van Brocklin, Corvallis, OR (US); Eric T. Martin, Corvallis, OR (US); Stanley J. Wang, Albany, OR (US); Adam L. Ghozeil, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: HEWLETT-PACKARD COMPANY

(21) Appl. No.: 10/848,961

(22) Filed: May 18, 2004

Related U.S. Application Data
(63) Continuation-in-part of application No. 10/141,609, filed on May 7, 2002.

(51) Int. Cl. H01L 29/06

(52) U.S. Cl. 257/414; 365/174

(57) ABSTRACT

Devices and methods for controlling a MEMS actuator are disclosed. The device includes a pair of parallel plates having a gap therebetween. The size of the gap is responsive to a voltage differential between the pair of plates. The device also includes a controller adapted to apply a voltage profile to at least one of the pair of plates to maintain a desired gap size. The voltage profile has a time-varying voltage.

### RELATED APPLICATIONS

This application is a continuation-in-part of U.S. patent application Ser. No. 10/141,609, titled “CHARGE CONTROL OF MICRO-ELECTROMECHANICAL DEVICE,” filed Apr. 30, 2003, which is hereby incorporated by reference in its entirety.

### BACKGROUND

MEMS devices have many applications, including uses in optical devices such as digital projectors. For example, a MEMS device known as a diffractive light device (DLD) may be implemented in a digital projector for processing a source light into an image.

An embodiment of a typical DLD is illustrated in FIG. 1. The DLD 100 includes a bottom plate 140 and a parallel pixel plate 110. The bottom plate is mounted on a base substrate 150. The pixel plate is mounted on posts 130 through flexures 120. In certain embodiments, the flexures 120 may be replaced by another resilient component, such as a spring, mounted on the posts 130. A gap 160 is formed between the bottom plate 140 and the pixel plate 110.

The DLD 100 generates a color for a pixel of an image by varying the size of the gap 160 to alter an interference pattern of light reflected from the DLD 100. Light 170 from a source is partially reflected (reflected light 180) by the top surface of the pixel plate 110. A portion of the source light 170 passes through the pixel plate 110 and is reflected by the bottom plate 140 (shown as line 190). The desired color can be formed with the interference pattern between the reflected lights 180, 190 by appropriately controlling the size of the gap 160 between the plates 140, 150.

The size of the gap 160 results from a combination of electrostatic forces due to the voltage differential and mechanical forces due to the flexures 120, for example. The size of the gap 160 may be controlled by a voltage differential between the plates 110, 140. In certain cases, the bottom plate 140 is held at a constant DC bias, while the pixel plate 110 is associated with a variable reference voltage. When a certain gap size is desired, the reference voltage applied to the pixel plate 110 is set at a predetermined level.

Conventional control systems and methods for controlling the gap between the plates apply a DC voltage differential that is adjusted to one value for one gap and another value for another gap. Such systems provide a limited gap size range. Conventional systems limit stable displacement of the pixel plate by approximately one-third of the size of the initial gap. Moving a pixel plate by more than that amount creates an instability known as the “pull-in” effect, which results in the two plates snapping together. For more details on the “pull-in” effect, reference may be made to “Charge Control of Parallel-Plate, Electrostatic Actuators and the Tip-In Instability,” JOURNAL OF MICROELECTROMECHANICAL SYSTEMS, Vol. 12, No. 5, October 2003.

It is desirable to provide control systems and methods that provide a greater range of gap sizes without causing instabilities. A larger range of gap sizes can, for example, allow achievement of a wider spectrum of colors in a digital projector, as well as increased reliability and improved performance.

### SUMMARY

One embodiment of the invention relates to a MEMS device. The device includes a pair of parallel plates having a gap therebetween. The size of the gap is responsive to a voltage differential between the pair of plates. The device also includes a controller adapted to apply a voltage profile to at least one of the pair of plates to maintain a desired gap size. The voltage profile has a time-varying voltage.

It is to be understood that both the foregoing general description and the following detailed description are exemplary and exemplary only, and are not restrictive of the invention as claimed.

### BRIEF DESCRIPTION OF THE DRAWINGS

FIG. 1 is a side view of a typical diffractive light device (DLD);

FIG. 2 is a schematic illustration of an embodiment of an optical device;

FIG. 3 illustrates an embodiment of a MEMS device with a controller;

FIG. 4A is a chart illustrating a convergence to a desired gap size using an embodiment of a control system;

FIG. 4B illustrates the gap size and voltage profile for a segment of the gap-size profile illustrated in FIG. 4A;

FIG. 5 is a chart illustrating another embodiment of a voltage profile for control of a MEMS device; and

FIG. 6 is a chart illustrating another embodiment of a voltage profile for control of a MEMS device.

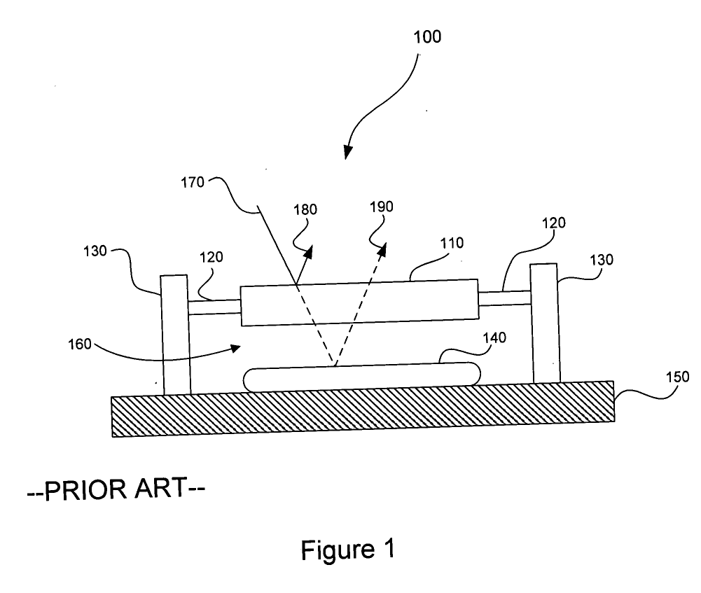

### DETAILED DESCRIPTION

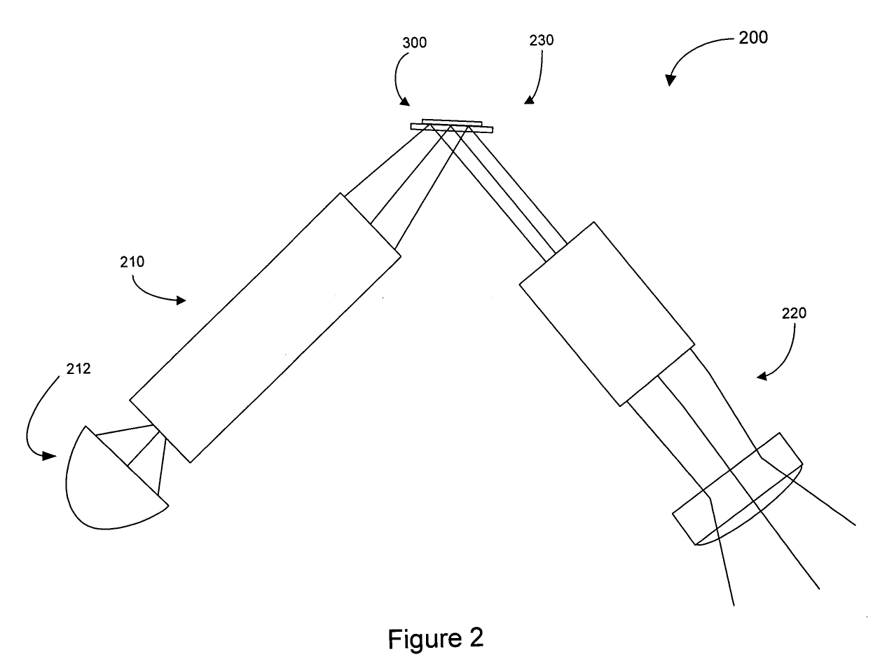

An embodiment of an optical device, such as a digital projector, is illustrated in FIG. 2. The projector 200 includes an illumination portion 210, a projection portion 220 and an image processing portion 230. The illumination portion 210 includes a light source 212 and one or more lenses or other components directing the light to the image processing portion 230, which may include a DLD 300. The processed image is then directed from the image processing portion 230 through the projection portion 220 to, for example, a screen (not shown).

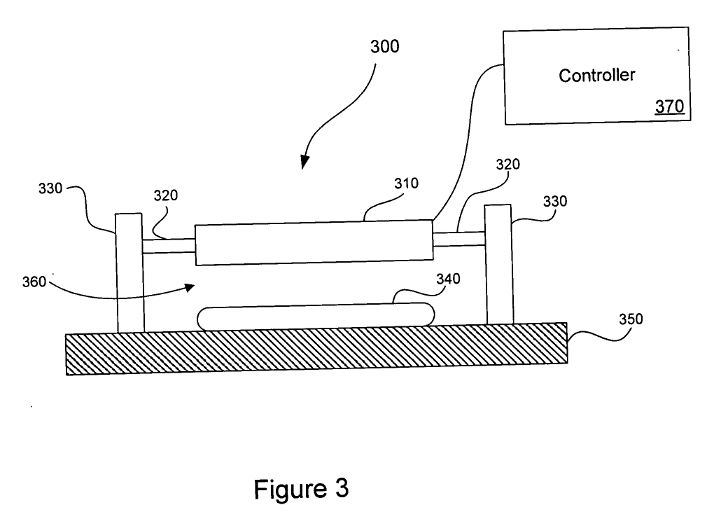

Referring to FIG. 3, a cross-sectional view of an embodiment of a MEMS device is illustrated. The illustrated MEMS device is a diffractive light device (DLD) 300 which may be implemented in an optical device, such as a digital projector, for example. The DLD 300 includes a pixel plate 310 mounted on posts 330 through flexures 320. A bottom plate 340 is mounted on a base substrate 350 and is positioned below the pixel plate 310.

The pixel plate 310 and the bottom plate 340 are positioned to form a gap 360 therebetween. In a DLD, the size of the gap 360 is varied to control the color by changing the interference pattern of light reflected by the DLD. The size of the gap 360 is a function of electrostatic forces between the plates 310, 340 and mechanical forces, such as those that may be exerted by the flexures 320, for example. For controlling the DLD, the size of the gap 360 is responsive to a voltage differential between the pair of plates.

The DLD 300 is provided with a controller 370 adapted to control the voltage differential between the pixel plate 310 and the bottom plate 340. In one embodiment, the controller 370 is adapted to apply a voltage profile with an AC component to at least one of the pair of plates to maintain a desired gap size. The controller 370 may include a power source or may control the voltage applied to the plates by an external power source.

The controller 370 is adapted to apply a voltage profile which has a time-varying component in order to maintain a desired gap. The time variation may be implemented in a number of ways. In one embodiment, a DC voltage is applied at a duty cycle of less than 100 percent. Thus, the time variation in the voltage profile includes a DC voltage applied at certain times and a zero voltage applied at other times, as may be produced in a DC voltage profile having a duty cycle less than 100 percent, such as a pulse-width modulated voltage profile. As described below, other types of time-varying voltage profiles are also possible and are contemplated, including a sine-wave profile and a triangular-wave profile.

In an exemplary embodiment, the DLD 300 may have a square pixel plate 310 with each side having a length of 20 microns. The flexures 320 of the exemplary embodiment have a spring constant of 5 Newtons/meter, and the device 300 has a mechanical time constant of 0.5 μs.

The mechanical time constant is indicative of the responsiveness of the system to inputs or changes in input. For example, in the exemplary embodiment, the mechanical time constant represents the time delay between an application of a voltage differential and the movement of the pixel plate to a desired position. In devices with an exponential decay in their settling behavior, the mechanical time constant may be determined based on the plate having traveled a certain distance between a starting position and a desired position. The mechanical time constant is a function of, among other things, the material used in the flexures 320 and by an environment in which the device operates. For example, the mechanical time constant of a device may have one value when operating in an environment comprising air and another value when operating in an environment comprising helium.

For example, the DLD 300 of the exemplary embodiment is provided with an initial gap of 4000 Angstroms between the pixel plate 310 and the bottom plate 340. Using a conventional DC voltage control, the maximum range of the size of the gap is between 4000 and 2700 Angstroms. The smallest gap of 2700 Angstroms is reached when a voltage differential of approximately 5.4 Volts DC is applied across the plates. If a greater voltage differential is applied, the device experiences pull-in, and the plates snap together.

As noted above, the controller 370 of FIG. 3 is adapted to apply a voltage profile which has a time-varying component in order to maintain a desired gap. In particular embodiments, the voltage profile is periodic. Further, the period of the periodic voltage profile should be substantially less than the mechanical constant of the system. In a particular embodiment, the

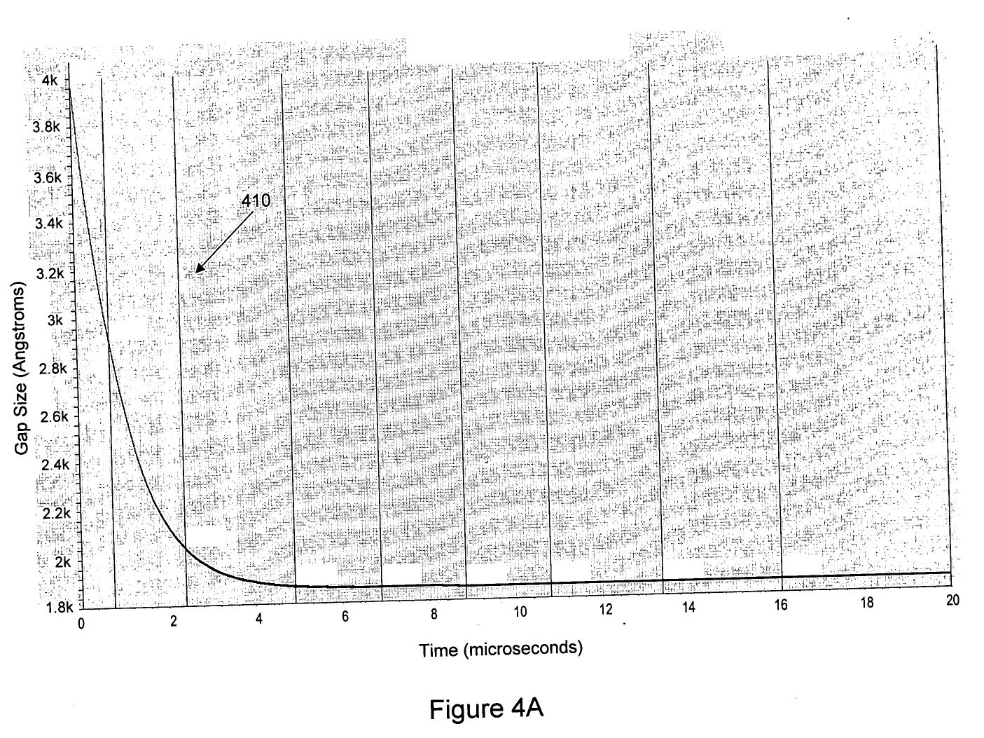

With one embodiment of the controller 370 coupled to the exemplary DLD 300, a new minimum gap size is achieved when the controller 370 applies a voltage profile having a 8.2-Volt square wave with a 30-percent duty cycle. With the characteristics of the exemplary embodiment described above, a stable gap size approximately 1850 Angstroms can be achieved. Results from a simulation supporting this gap size are described below with reference to FIGS. 4A and 4B.

Referring to FIG. 4A, a gap size profile 410 is illustrated for a case in which the starting gap size is 4000 Angstroms. By applying a 8.2-Volt square-wave voltage profile at 30 percent duty cycle, the gap size converges to approximately 1875 Angstroms in approximately 5 μs. The 30-percent duty-cycle square wave of the exemplary embodiment has a frequency of 200 MHz, or a period of 5 nanoseconds.

FIG. 4B provides a segment of the gap size profile 410 of FIG. 4A in greater detail along with the corresponding voltage profile 420 applied. The segment shown illustrates the gap-size profile 410 at convergence, after approximately 14 microseconds from the application of the voltage profile.

While the above-described, 30-percent duty-cycle, 8.2-volt square wave provides a stable gap range of between 1850 and 4000 Angstroms, beneficial ranges can be reached with a voltage profile having different combination of voltage and duty cycle. For example, Table 1 below illustrates results from simulations for one embodiment of a MEMS showing the minimum stable gap achieved while duty cycle is varied. As the results indicate, a reduction in the duty cycle below 100 percent can provide an increase in the range of stable gap sizes.

TABLE 1

| Duty Cycle (%) | Minimum Stable Gap (Ang) | Voltage (V) |
|---|---|---|
| 100 | 2780 | 5.45 |
| 95 | 2724 | 5.56 |
| 90 | 2702 | 5.71 |
| 80 | 2651 | 6.06 |
| 70 | 2602 | 6.46 |
| 60 | 2592 | 6.97 |
| 50 | 2431 | 7.35 |

Thus, the controller applies a certain voltage profile having a time-varying component to achieve and maintain a desired gap size. In order to change the gap size, the voltage profile applied by the controller may be changed to a different profile having a time-varying component. For example, the gap size may be determined by changing one or more components of the square-wave, such as the peak voltage or the duty cycle, for example.

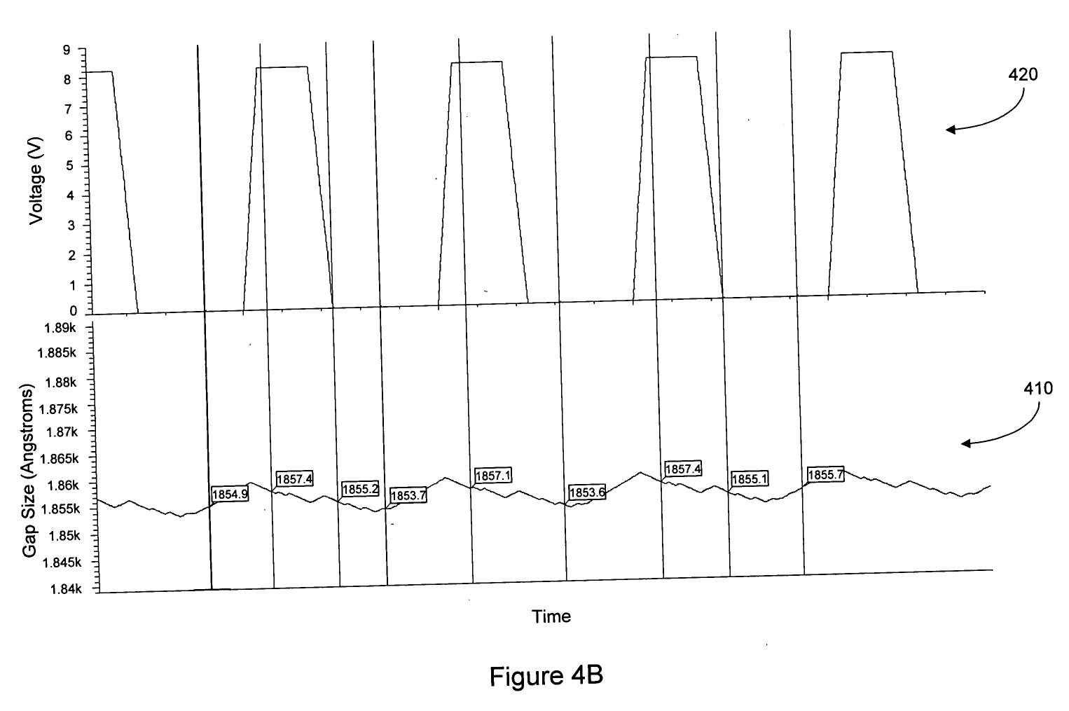

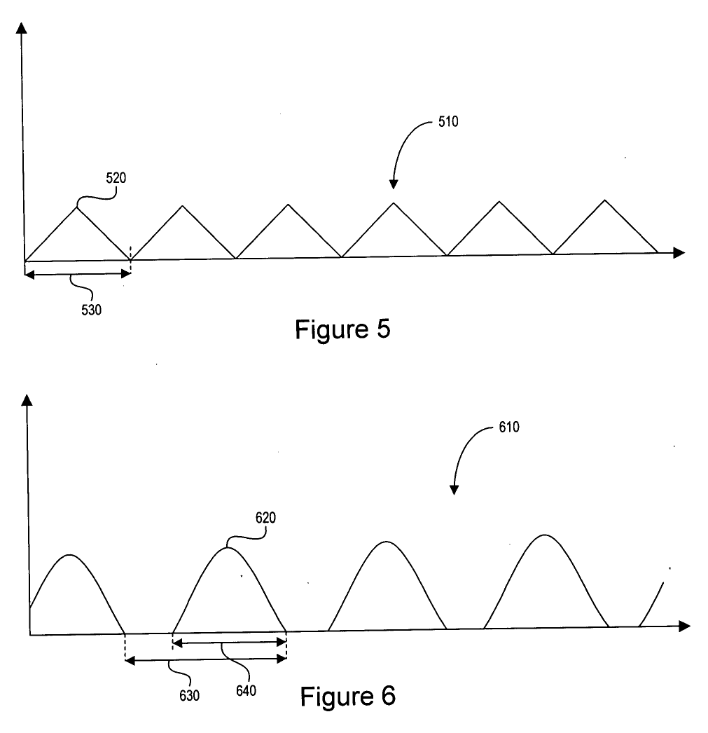

The voltage profile applied by the controller may be periodic, with or without a duty cycle. For example, the square voltage profile described above has a periodic profile with a duty cycle of 50 percent. In other embodiments, the voltage may vary between two non-zero values. Other exemplary periodic profiles with and without a duty cycle are illustrated in FIGS. 5 and 6.

FIG. 5 illustrates a voltage profile having a periodic triangular wave 510. Thus, a desired gap size may be achieved and maintained by applying a triangular wave voltage profile having a certain peak voltage 520 and a certain period 530. Further, a duty-cycle component (not shown) may be added to provide additional control. Thus, to change the gap size, a different triangular wave voltage profile may be applied having a different peak-voltage, period or duty cycle.

FIG. 6 illustrates a truncated sinusoidal voltage profile 610 applied by the controller. This profile 610 has a certain peak voltage 620, period 630 and a duty cycle 640 corresponding to a desired gap size. Again, for a different desired gap size, at least one of the peak voltage 620, the period 630 and the duty cycle 640 may be altered.

A triangular wave voltage profile (FIG. 5) and a sinusoidal voltage profile (FIG. 6) may offer additional advantages, such as reduced electromagnetic interference. Further, since the variation in voltage is gradual, components of the DLD, such as the flexures, are exposed to less shock.

Thus, the disclosed embodiments provide a MEMS control system and method which improves the performance capabilities of parallel-plate MEMS devices. In the case of a DLD, a broader spectrum of image data may be processed or generated.

The foregoing description of embodiments of the invention have been presented for purposes of illustration and description. It is not intended to be exhaustive or to limit the invention to the precise form disclosed, and modifications and variation are possible in light of the above teachings or may be acquired from practice of the invention. The embodiment was chosen and described in order to explain the principles of the invention and its practical application to enable one skilled in the art to utilize the invention in various embodiments and with various modification as are suited to the particular use contemplated. It is intended that the scope of the invention be defined by the claims appended hereto and their equivalents.

What is claimed is:

1. A MEMS device, comprising:
a pair of parallel plates having a gap therebetween, a size of said gap being responsive to a voltage differential between said pair of plates; and
a controller adapted to apply a voltage profile to at least one of the pair of plates to maintain a desired gap size, said voltage profile having a time-varying voltage.

2. The MEMS device according to claim 1, wherein the voltage profile is periodic.

3. The MEMS device according to claim 2, wherein the voltage profile has a period that is less than a mechanical time constant of the plates.

4. The MEMS device according to claim 2, wherein the voltage profile includes a square-wave voltage profile with a duty cycle of less than 100 percent.

5. The MEMS device according to claim 4, wherein the voltage profile includes a square-wave voltage profile with a duty cycle of less than 90 percent.

6. The MEMS device according to claim 5, wherein the voltage profile includes a square-wave voltage profile with a duty cycle of less than 80 percent.

7. The MEMS device according to claim 6, wherein the voltage profile includes a square-wave voltage profile with a duty cycle of approximately 50 percent.

8. The MEMS device according to claim 2, wherein the voltage profile includes a sinusoidal voltage profile.

9. The MEMS device according to claim 8, wherein the sinusoidal voltage profile is truncated.

10. The MEMS device according to claim 2, wherein the voltage profile includes a triangular-wave voltage profile.

11. The MEMS device according to claim 1, wherein said pair of plates form a diffractive light device.

12. The MEMS device according to claim 1, wherein said controller is adapted to change said size of said gap by changing said voltage profile.

13. An optical device, comprising:
an optical MEMS device including a pair of plates having a gap therebetween, a size of said gap being responsive to a voltage differential between said pair of plates; and
a controller adapted to apply a voltage profile to at least one of the pair of plates to maintain a desired gap size, said voltage profile having a time-varying voltage.

14. The optical device according to claim 13, wherein the voltage profile is periodic.

15. The optical device according to claim 14, wherein the voltage profile has a period that is less than a mechanical time constant of the plates.

16. The optical device according to claim 14, wherein the voltage profile includes a square-wave voltage profile with a duty cycle of less than 100 percent.

17. The optical device according to claim 16, wherein the voltage profile includes a square-wave voltage profile with a duty cycle of less than 90 percent.

18. The optical device according to claim 17, wherein the voltage profile includes a square-wave voltage profile with a duty cycle of less than 80 percent.

19. The optical device according to claim 18, wherein the voltage profile includes a square-wave voltage profile with a duty cycle of approximately 50 percent.

20. The optical device according to claim 13, wherein said pair of plates form a diffractive light device.

21. The optical device according to claim 13, wherein said controller is adapted to change said size of said gap by changing said voltage profile.

22. The optical device according to claim 13, wherein the optical device is a digital projector.

23. A method of controlling a MEMS actuator having a pair of parallel plates with a gap therebetween, a size of said gap being responsive to a voltage differential between said plates, the method comprising:
applying a voltage profile to at least one of a pair of plates to maintain a desired gap size, said voltage profile having a time-varying voltage.

24. The method according to claim 23, wherein said step of applying a voltage profile includes applying a periodic voltage profile.

25. The method according to claim 24, wherein said step of applying a voltage profile includes applying a periodic voltage profile having a period that is less than a mechanical time constant of the plates.

26. The method according to claim 24, wherein said step of applying a voltage profile includes applying a square-wave voltage profile with a duty cycle of less than 100 percent.

27. The method according to claim 26, wherein said step of applying a voltage profile includes applying a square-wave voltage profile with a duty cycle of less than 90 percent.

28. The method according to claim 27, wherein said step of applying a voltage profile includes applying a square-wave voltage profile with a duty cycle of less than 80 percent.

29. The method according to claim 28, wherein said step of applying a voltage profile includes applying a square-wave voltage profile with a duty cycle of approximately 50 percent.

30. The method according to claim 24, wherein said step of applying a voltage profile includes applying a sinusoidal voltage profile.

31. The method according to claim 30, wherein the sinusoidal voltage profile is truncated.

32. The method according to claim 24, wherein said step of applying a voltage profile includes applying a triangular-wave voltage profile.

33. The method according to claim 24, further comprising:
changing said voltage profile to change said size of said gap.

34. A MEMS device, comprising:
means for forming a gap between a pair of parallel plates, a size of said gap being responsive to a voltage differential between said pair of plates; and
means for applying a voltage profile to at least one of the pair of plates to maintain a desired gap size, said voltage profile having a time-varying voltage.
